(19) United States
(12) Patent Application Publication
(10) Pub. No.: US 2026/0003271 A1
(43) Pub. Date: Jan. 1, 2026

(54) PHOTOSENSITIVE RESIN COMPOSITION, PHOTOSENSITIVE RESIN LAYER, AND SEMICONDUCTOR DEVICE USING THE SAME

(71) Applicant: SAMSUNG SDI CO., LTD., Yongin-si (KR)

(72) Inventors: Sang Soo KIM, Suwon-si (KR); Taek-Jin BAEK, Suwon-si (KR); Heekyoung KANG, Suwon-si (KR); Jinhee KANG, Suwon-si (KR); Jiyu KIM, Suwon-si (KR); Mingyum KIM, Suwon-si (KR); Chungbeum HONG, Suwon-si (KR); Byeongwook PARK, Suwon-si (KR); Yushin PARK, Suwon-si (KR)

(21) Appl. No.: 18/986,360

(22) Filed: Dec. 18, 2024

(30) Foreign Application Priority Data
Jun. 26, 2024 (KR) 10-2024-0083885

(51) Int. Cl. G03F 7/028; C08G 73/12; G03F 7/037; G03F 7/16; H01L 23/532

(52) U.S. Cl. CPC G03F 7/028; C08G 73/127; G03F 7/037; G03F 7/168; H01L 23/5329

(57) ABSTRACT

A photosensitive resin composition, a photosensitive resin layer manufactured using the photosensitive resin composition, and a semiconductor device including the photosensitive resin layer are provided. The photosensitive resin composition includes (A) a resin, (B) a photopolymerizable compound, (C) a photopolymerization initiator, and (D) a solvent. The photopolymerizable compound includes a compound represented by Chemical Formula 1.

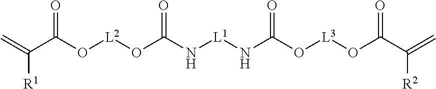

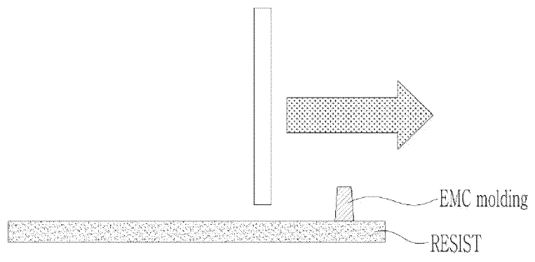

### CROSS-REFERENCE TO RELATED APPLICATION

This application claims priority to and the benefit of Korean Patent Application No. 10-2024-0083885, filed on Jun. 26, 2024, in the Korean Intellectual Property Office, the entire disclosure of which is incorporated herein by reference.

### BACKGROUND

### 1. Field

According to one or more embodiments, the present disclosure relates to a photosensitive resin composition, a photosensitive resin layer using the same, and a semiconductor device.

### 2. Description of the Related Art

A method of sealing a semiconductor device with an epoxy resin composition is being commercially practiced for the purpose of protecting the semiconductor device from external environments such as moisture or mechanical impact and/or the like. A comparable processing method for semiconductor device-sealing include cutting (dicing) a wafer to manufacture semiconductor chips and then, packing a semiconductor chip unit. Recently, a process of performing the packaging first (e.g., in a wafer state, or a panel state which is larger than the semiconductor chips), and then, cutting (dicing) the packaged wafer or panel into the semiconductor chips has been developed. In general, the comparable method is called to be “chip scale packaging” (CSP), and the more recent process is called to be “wafer level packaging” (WLP) and “panel level packaging” (PLP).

The wafer level packaging (WLP) has advantages of a higher process yield than the chip scale packaging (CSP) and a smaller semiconductor-mounting space due to its thin package thickness. However, the wafer level packaging (WLP) or the panel level packaging (PLP) has a larger filming area than the chip scale packaging (CSP) of sealing individual chips and presents the problem of significantly generating warpage due to a thermal expansion rate difference between wafer or panel and a sealing material. The warpage, if ever occurs, may affect a yield and wafer handling in the subsequent process. In some embodiments, the wafer level packaging (WLP) or the panel level packaging (PLP) currently uses a liquid type (or kind) epoxy resin or silicone resin as a main sealant but has problems of having a low content of an inorganic filler in a liquid type (or kind) composition and low reliability of a semiconductor package after the sealing as the resin also uses liquid monomolecules.

Accordingly, development of an insulating layer for a redistribution layer (RDL), which may achieve little warpage, even when the wafer level packaging (WLP) or the panel level packaging (PLP) is applied, and excellent reliability, is desired or required.

In order to meet the desire or requirement, development of a photosensitive resin composition for forming an insulating layer for a redistribution layer is ongoing. In general, a photosensitive polyimide resin composition, in which photosensitivity is imparted to a polyimide resin itself, is mainly used. The photosensitive polyimide resin composition may simplify a pattern forming process. However, in the case of an insulating layer (cured layer) for a redistribution layer manufactured using a comparable photosensitive polyimide resin composition, there is a problem that corrosion resistance and chemical resistance are reduced. For example, a resin for an insulating layer for a redistribution layer requires low-temperature curing, but comparable photosensitive polyimide resins cannot be cured at low temperatures, and thus there is a problem that high heat resistance and high reliability cannot be achieved.

### SUMMARY

One or more aspects are directed toward a photosensitive resin composition having a low coefficient of thermal expansion, excellent adhesive strength to a metal layer, and improved reliability by using a compound having a structure as described herein as an additive.

One or more aspects are directed toward a photosensitive resin layer manufactured using the photosensitive resin composition.

One or more aspects are directed toward a semiconductor device including the photosensitive resin layer.

Additional aspects will be set forth in part in the description which follows and, in part, will be apparent from the description, or may be learned by practice of the presented embodiments of the disclosure.

According to one or more embodiments a photosensitive resin composition includes (A) a resin; (B) a photopolymerizable compound including a compound represented by Chemical Formula 1; (C) a photopolymerization initiator; and (D) a solvent.

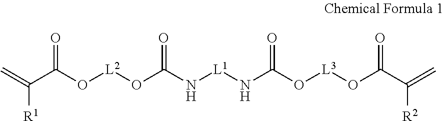

In Chemical Formula 1,
R¹ and R² may each independently be a hydrogen atom or a substituted or unsubstituted C1 to C20 alkyl group,
L¹ to L³ may each independently be a substituted or unsubstituted C1 to C20 alkylene group, a substituted or unsubstituted C3 to C20 cycloalkylene group, a substituted or unsubstituted C6 to C20 arylene group, or a combination thereof.

In Chemical Formula 1, R¹ and R² may each independently be a methyl group.

In Chemical Formula 1, L² and L³ may each independently be an unsubstituted C1 to C20 alkylene group.

In Chemical Formula 1, L¹ may be represented by Chemical Formula L.

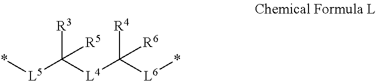

In Chemical Formula L,
R³ to R⁶ may each independently be a hydrogen atom or a substituted or unsubstituted C1 to C20 alkyl group, provided that at least one selected from among (e.g., of) R³ and R⁵ is (e.g., necessarily) a substituted or unsubstituted C1 to C20 alkyl group, and at least one selected from among (e.g., of) R⁴ and R⁶ is (e.g., necessarily) a substituted or unsubstituted C1 to C20 alkyl group, and
L⁴ to L⁶ may each independently be an unsubstituted C1 to C20 alkylene group.

In Chemical Formula L, L⁵ and L⁶ may be different from each other.

The compound represented by Chemical Formula 1 may have an asymmetric structure.

The resin may be a polyamic acid or polyamic ester resin including a structural unit represented by Chemical Formula 2.

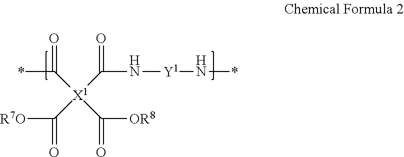

In Chemical Formula 2,
X¹ may be a moiety derived from a monoanhydride monomer or a dianhydride monomer,
Y¹ may be a moiety derived from a diamine monomer, and
R⁷ and R⁸ may each independently be a substituted or unsubstituted C1 to C20 alkyl group, a substituted or unsubstituted C3 to C20 cycloalkyl group, a substituted or unsubstituted C6 to C20 aryl group or a substituted or unsubstituted C2 to C20 heterocyclic group.

The monoanhydride monomer or dianhydride monomer may be represented by Chemical Formula 2-1 or Chemical Formula 2-2.

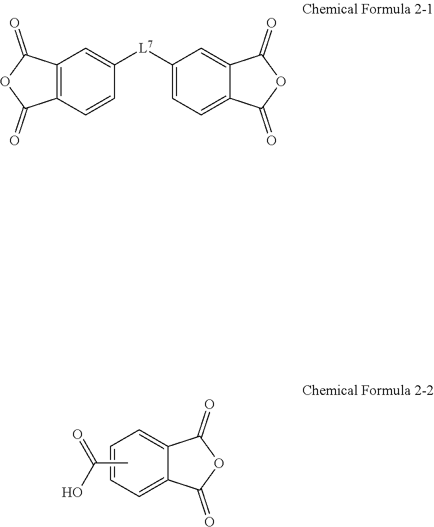

In Chemical Formula 2-1,
L⁷ may be a single bond (e.g., a single covalent bond), *—O—*, *—S—*, *—C≡C—*, *—C(═O)—*, *—C(═O)O—*, *—NR⁰—* (R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

The resin may include a moiety derived from the monoanhydride monomer represented by Chemical Formula 2-2.

The diamine monomer may be represented by Chemical Formula 2-3 or Chemical Formula 2-4.

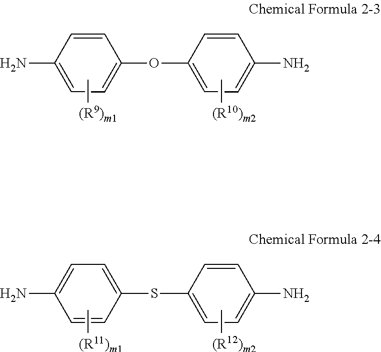

In Chemical Formula 2-3 and Chemical Formula 2-4,
R¹¹ and R¹² may each independently be a halogen atom, a hydroxy group, a substituted or unsubstituted C1 to C20 alkyl group, or substituted or unsubstituted C1 to C20 alkoxy group, and
m1 and m2 may each independently be an integer ranging from 0 to 4.

The photopolymerizable compound may further include a compound having a different structure from the compound represented by Chemical Formula 1.

The photosensitive resin composition may include the photopolymerizable compound in an amount of about 1 part by weight to about 30 parts by weight, the photopolymerization initiator in an amount of about 1 part by weight to about 10 parts by weight, and the solvent in an amount of about 100 parts by weight to about 500 parts by weight, based on 100 parts by weight of the resin.

The photosensitive resin composition may further include an additive such as diacid, alkanolamine, a leveling agent, a silane coupling agent, a surfactant, an epoxy compound, a thermal latent acid generator, or a combination thereof.

The photosensitive resin composition may be a negative type (or kind) photosensitive resin composition.

Some example embodiments provide a photosensitive resin layer manufactured using the photosensitive resin composition.

The photosensitive resin layer may be a semiconductor redistribution layer insulating layer.

Some example embodiments provide a semiconductor device including the photosensitive resin layer.

Other embodiments are included in the following detailed description.

The photosensitive resin composition according to some example embodiments includes a compound having a structure as described herein as an additive, thereby improving adhesive strength to a metal layer (e.g., a copper layer, a silicon layer, a titanium layer, and/or the like) and lowering a coefficient of thermal expansion, thereby enabling implementation of an insulating layer (e.g., an electrically insulating layer) for a semiconductor redistribution layer with excellent reliability.

### BRIEF DESCRIPTION OF THE DRAWING

The accompanying drawing is included to provide a further understanding of the present disclosure and is incorporated in and constitutes a part of this specification. The drawing illustrates embodiments of the present disclosure and, together with the description, serves to explain principles of the present disclosure.

The drawing is a schematic view of a die shear tester device for evaluating the adhesive strength of a photosensitive resin composition.

### DETAILED DESCRIPTION

Hereinafter, embodiments of the present disclosure are described in detail to such an extent that those skilled in the art easily implement the present disclosure. In order to sufficiently understand the configuration and effect of the present disclosure, one or more embodiments are described with reference to the accompanying drawing. However, these embodiments are exemplary, and the present disclosure is not limited thereto.

In this description, it will be understood that, if (e.g., when) an element or component is referred to as being on another element, the element or component may be directly on the other element, or intervening elements may be present between therebetween. In contrast, if (e.g., when) an element is referred to as being “directly on” another element, there are no intervening elements present. In the drawings, thicknesses of some components are exaggerated for effectively explaining the technical contents. Like reference numerals refer to like elements throughout, and duplicative descriptions thereof may not be provided the specification.

Unless otherwise specially noted in this description, the expression of singular form (e.g., “a,” “an,” and/or “the”) may include the expression of plural form, including “at least one,” unless the context clearly dictates otherwise. In some embodiments, unless otherwise specially noted, the phrase “A or B” may indicate “A but not B”, “B but not A”, and “A and B”. The terms “comprises,” “includes,” “comprising,” “including,” “comprise,” “include,” “having,” “has,” and/or “have,” as used in this description, are intended to designate the presence of an embodied aspect, number, step (e.g., act or task), element, and/or a (e.g., any suitable) combination thereof, and do not preclude or exclude the presence or addition of one or more other features, numbers, steps (e.g., acts or tasks), elements, components, and/or a (e.g., any suitable) combination thereof.

As used herein, the term “combination thereof” may refer to a mixture, a stack, a composite, a copolymer, an alloy, a blend, or a reaction product.

In one or more embodiments, the term “layer” herein includes a shape formed on the whole surface or on a partial surface.

It will be understood that, although the terms “first,” “second,” “third,” and/or the like may be utilized herein to describe one or more suitable elements, components, regions, layers and/or sections, these elements, components, regions, layers and/or sections should not be limited by these terms. These terms are only utilized to distinguish one element, component, region, layer or section from another element, component, region, layer, or section. Thus, a first element, component, region, layer, or section described herein may be termed a second element, component, region, layer or section without departing from the teachings set forth herein.

As utilized herein, the term “and/or” includes any, and all, combinations of one or more of the associated listed items. Expressions such as “at least one of,” “one of,” and “selected from,” if (e.g., when) preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

Spatially relative terms, such as “beneath,” “below,” “lower,” “above,” “upper” and/or the like, may be utilized herein to easily describe the relationship between one element or feature and another element or feature. It will be understood that the spatially relative terms are intended to encompass different orientations of a device in utilization or operation in addition to the orientation illustrated in the drawings. For example, if (e.g., when) the device in the drawings is turned over, elements described as “below” or “beneath” other elements or features will be oriented “above” the other elements or features. Thus, the example term “below” can encompass both (e.g., simultaneously) the orientations of above and below. The device may be otherwise oriented (rotated 90 degrees or at other orientations), and the spatially relative terms utilized herein may be interpreted accordingly.

The terminology utilized herein is utilized for the purpose of describing the embodiments, and is not intended to limit the present disclosure. Unless otherwise defined, all terms (including chemical, technical and scientific terms) utilized herein have the same meaning as commonly understood by one of ordinary skill in the art to which this disclosure pertains. It will be further understood that terms, such as those defined in commonly utilized dictionaries, should be interpreted as having a meaning that is consistent with their meaning in the context of the related art and the present disclosure, and will not be interpreted in an idealized or overly formal sense.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In this context, “consisting essentially of” indicates that any additional components will not materially affect the chemical, physical, optical or electrical properties of the semiconductor film.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C7 to C20 arylalkyl group, “alkylene group” refers to a C1 to C20 alkylene group, “arylene group” refers to a C6 to C20 arylene group, “alkylarylene group” refers to a C7 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen of a compound by a substituent selected from a halogen atom (F, Cl, Br, or I), a C1 to C20 alkyl group substituted with a halogen atom such as a trifluoromethyl group, a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate.”

As used herein, when a definition is not otherwise provided, the term “combination” refers to mixing or copolymerization. Also, “copolymerization” refers to block copolymerization, alternating copolymerization, or random copolymerization, and “copolymer” refers to a block copolymer, an alternating copolymer, or a random copolymer.

As used herein, when specific definition is not otherwise provided, an unsaturated bond includes not only multiple bonds between carbon and carbon atoms, but also those containing other molecules, such as a carbonyl bond and an azo bond.

In the chemical formula of the present specification, unless a specific definition is otherwise provided, hydrogen is boned at the position when a chemical bond is not drawn where supposed to be given.

As used herein, when a definition is not otherwise provided, “*” refers to a linking part between the same or different atoms, or chemical formulas.

### Resin Composition

A photosensitive resin composition according to some example embodiments includes (A) a resin; (B) a photopolymerizable compound including a compound represented by Chemical Formula 1; (C) a photopolymerization initiator; and (D) a solvent.

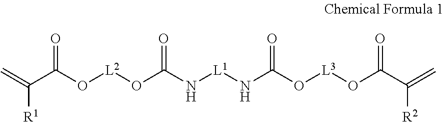

In Chemical Formula 1,
R¹ and R² are each independently a hydrogen atom or a substituted or unsubstituted C1 to C20 alkyl group, and
L¹ to L³ are each independently a substituted or unsubstituted C1 to C20 alkylene group, a substituted or unsubstituted C3 to C20 cycloalkylene group, a substituted or unsubstituted C6 to C20 arylene group, or a combination thereof.

Hereinafter, each component is described in detail.

### Resin

The resin used in the photosensitive resin composition according to some example embodiments may be a polyamic acid or polyamic ester-based resin, and the polyamic acid or polyamic ester-based resin may include a structural unit represented by Chemical Formula 2.

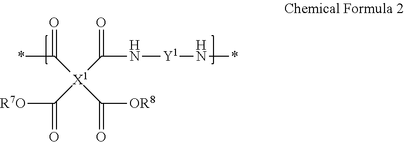

In Chemical Formula 2,
X¹ may be a moiety derived from a monoanhydride monomer or a dianhydride monomer,
Y¹ may be a moiety derived from a diamine monomer, and
R⁷ and R⁸ may each independently be a substituted or unsubstituted C1 to C20 alkyl group, a substituted or unsubstituted C3 to C20 cycloalkyl group, a substituted or unsubstituted C6 to C20 aryl group or a substituted or unsubstituted C2 to C20 heterocyclic group.

For example, R⁷ and R⁸ may each independently be a C1 to C20 alkyl group substituted or unsubstituted with a (meth)acrylate group.

The polyamic acid or polyamic ester resin including the structural unit represented by Chemical Formula 2 may maintain low sensitivity without occurrence of scum in the lower layer, lower the coefficient of thermal expansion (CTE), and provide an effect of improving adhesive strength to a metal layer, and in addition, can be easily applied to a negative type (or kind) composition to greatly improve developability.

In general, a resin with a closed-ring structure has a problem of slightly deteriorating film characteristics, if (e.g., when) cured at a low temperature, but because the polyamic acid or polyamic ester resin including the structural unit represented by Chemical Formula 2 is used with the compound represented by Chemical Formula 1, the photosensitive resin composition according to some example embodiments may be suitable for low-temperature curing, providing an insulating layer (cured layer, e.g., an electrically insulating layer) having excellent film characteristics.

For example, the photosensitive resin composition according to some example embodiments is line with the recent trend toward a multi-layered redistribution layer in terms of improving a crack or a delamination rate in a reliable environment by making a copper metal of the redistribution layer and an insulating layer material (e.g., an electrically insulating layer material) of the redistribution layer have similar CTEs.

For example, the polyamic acid or polyamic ester resin including the structural unit represented by Chemical Formula 2 may be a polymer between a ‘monoanhydride monomer or diamine hydride monomer’ and a ‘diamine monomer.’

For example, the diamine monomer may be represented by Chemical Formula 2-3 or Chemical Formula 2-4.

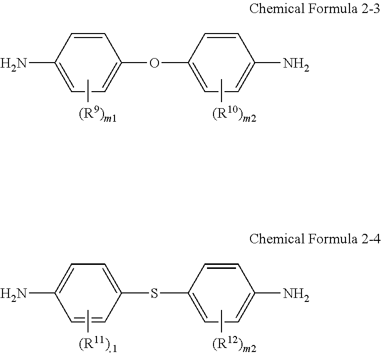

In Chemical Formula 2-3 and Chemical Formula 2-4,
R¹¹ and R¹² may each independently be a halogen atom, a hydroxy group, a substituted or unsubstituted C1 to C20 alkyl group, or a substituted or unsubstituted C1 to C20 alkoxy group, and
m1 and m2 may each independently be an integer ranging from 0 to 4.

For example, the monoanhydride monomer or dianhydride monomer may include a monomer represented by Chemical Formula 2-1 or Chemical Formula 2-2, but is not necessarily limited thereto.

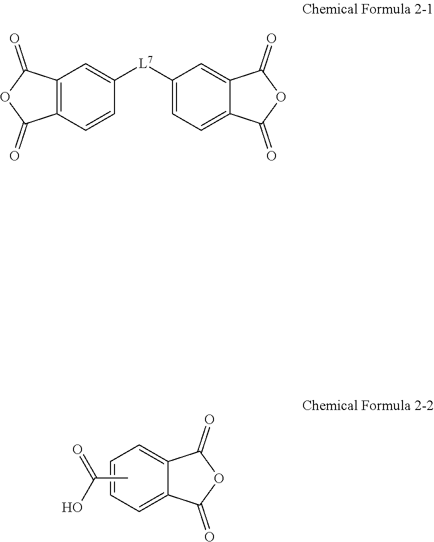

In Chemical Formula 2-1,
L⁷ may be a single bond (e.g., a single covalent bond), *—O—*, *—S—*, *—C≡C—*, *—C(═O)—*, *—C(═O)O—*, *—NR⁰—* (R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

For example, if (e.g., when) L⁷ is a substituted or unsubstituted C1 to C20 alkylene group, it may be a C1 to C20 alkylene group substituted or unsubstituted with a trifluoroalkyl group.

For example, the resin may include the moiety derived from the monoanhydride monomer represented by Chemical Formula 2-2, in which case the resin may be advantageous in terms of sensitivity, coefficient of thermal expansion, and adhesive strength compared to a case in which the resin does not include the moiety derived from the monoanhydride monomer represented by Chemical Formula 2-2.

For example, in Chemical Formula 2, X¹ may be the moiety derived from the monoanhydride monomer represented by Chemical Formula 2-2 or may include (e.g., consist of) the moiety derived from the dianhydride monomer represented by Chemical Formula 2-1 (however, L⁷ is not a single bond) and the moiety derived from the monoanhydride monomer represented by Chemical Formula 2-2. And, if (e.g., when) the X¹ includes (e.g., consists of) the moiety derived from the dianhydride monomer represented by Chemical Formula 2-1 (however, L⁷ is not a single bond) moiety and the moiety derived from the monoanhydride monomer represented by Chemical Formula 2-2, the mole number of the moiety derived from the dianhydride monomer represented by Chemical Formula 2-1 (however, L⁷ is not a single bond) may be higher than that of the moiety derived from the monoanhydride monomer represented by Chemical Formula 2-2. This may be advantageous in terms of sensitivity, a coefficient of thermal expansion, and adhesive strength and in particular, significantly reduce the coefficient of thermal expansion.

A weight average molecular weight (Mw) of the polyamic acid or polyamic ester-based resin may be about 3,000 gram per mole (g/mol) to about 300,000 g/mol. If the weight average molecular weight of the polyamic acid or polyamic ester-based resin is within the described range, sufficient physical properties can be obtained, and the solubility in organic solvents is improved, making it easy to handle.

### Photopolymerizable Compound

The photopolymerizable compound in the photosensitive resin composition according to some example embodiments includes a compound represented by Chemical Formula 1.

If the compound represented by Chemical Formula 1 is included, this compound is used with the described resin to provide a photosensitive resin composition all improving scum characteristics, sensitivity, a coefficient of thermal expansion, and adhesive strength as well as advantageous for low-temperature curing, which may be very suitable for use as an insulating layer (e.g., an electrically insulating layer) between semiconductor redistribution layers.

The compound represented by Chemical Formula 1 has (meth)acrylate groups at both terminal ends and an intermediate linking group liking them each other and additionally, a urethane linking group between each of the (meth)acrylate groups and the intermediate linking group. Due to this structure, the compound, if (e.g., when) mixed with the resin and, for example, the polyamic acid or polyamic ester-based resin, may lower a coefficient of thermal expansion and improve adhesive strength, and accordingly the photosensitive resin composition according to some example embodiments may be very advantageous for use as an insulating layer (e.g., an electrically insulating layer) for semiconductor redistribution layers.

For example, in Chemical Formula 1, R¹ and R² may each independently be a methyl group. For example, the compound represented by Chemical Formula 1 may include a methacrylate group at both terminal ends.

For example, in Chemical Formula 1, L² and L³ may each independently be an unsubstituted C1 to C20 alkylene group, but are not necessarily limited thereto.

For example, in Chemical Formula 1, L¹ may be represented by Chemical Formula L.

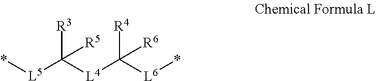

In Chemical Formula L,
R³ to R⁶ may each independently be a hydrogen atom or a substituted or unsubstituted C1 to C20 alkyl group, provided that at least one of (e.g., selected from among) R³ and R⁵ is (e.g., necessarily) a substituted or unsubstituted C1 to C20 alkyl group, and at least one of (e.g., selected from among) R⁴ and R⁶ is (e.g., necessarily) a substituted or unsubstituted C1 to C20 alkyl group, and
L⁴ to L⁶ may each independently be a unsubstituted C1 to C20 alkylene group.

For example, in Chemical Formula L, L⁵ and L⁶ may be different from each other. For example, the compound represented by Chemical Formula 1 may have an asymmetric structure.

By having a linking group such as Chemical Formula L as an intermediate linking group, it may be easy to simultaneously improve sensitivity, coefficient of thermal expansion, and adhesive strength, and if (e.g., when) the compound represented by Chemical Formula 1 has an asymmetric structure, it may be even easier to implement the described effects compared to if (e.g., when) it has a symmetric structure.

For example, the compound represented by Chemical Formula 1 may be a single compound or a mixture of two or more compounds included in the scope of Chemical Formula 1. For example, if the compound represented by Chemical Formula 1 exists in the form of a mixture of two compounds, the mixture may be a mixture including the two compounds in a weight ratio of about 50:50.

The compound represented by Chemical Formula 1 may be included in an amount of about 1 part by weight to about 10 parts by weight, for example about 1 part by weight to about 5 parts by weight, based on 100 parts by weight of the resin. If (e.g., when) the compound represented by Chemical Formula 1 is included within the described range, the adhesive strength with the resin is improved, and the sensitivity and adhesive strength characteristics can also be improved.

For example, the photopolymerizable compound may further include a compound having a different structure from the compound represented by Chemical Formula 1. In this case, the compound represented by Chemical Formula 1 may be included in a smaller weight than a compound having a different structure.

For example, a compound having a different structure from the compound represented by Chemical Formula 1 may be represented by Chemical Formula 6.

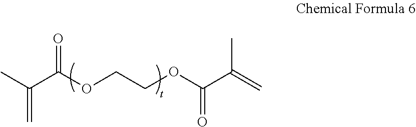

In Chemical Formula 6,
t may be an integer from 1 to 10, for example, an integer from 5 to 10.

For example, the compound represented by Chemical Formula 6 may be included in an amount of about 10 parts by weight to about 20 parts by weight, for example about 10 parts by weight to about 15 parts by weight, based on 100 parts by weight of the resin. If (e.g., when) the compound represented by Chemical Formula 6 is included within the described range, the effect of improving adhesive strength and sensitivity with the resin can be further increased.

In some embodiments, the photopolymerizable compound may further include a compound including at least two functional groups represented by Chemical Formula 3.

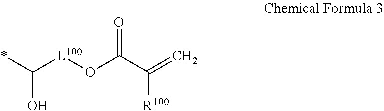

In Chemical Formula 3,
R¹⁰⁰ may be a hydrogen atom or a substituted or unsubstituted C1 to C10 alkyl group, and
L¹⁰⁰ may be a single bond (e.g., a single covalent bond) or a substituted or unsubstituted C1 to C10 alkylene group.

For example, the compound containing at least two functional groups represented by Chemical Formula 3 may include 2 to 6 functional groups represented by Chemical Formula 3. In this case, sufficient polymerization occurs during exposure in the pattern formation process to form a pattern with excellent heat resistance, light resistance, and chemical resistance.

For example, the compound containing at least two functional groups represented by Chemical Formula 3 may be a compound represented by any one selected from among (e.g., of) Chemical Formula 4 and Chemical Formula 5.

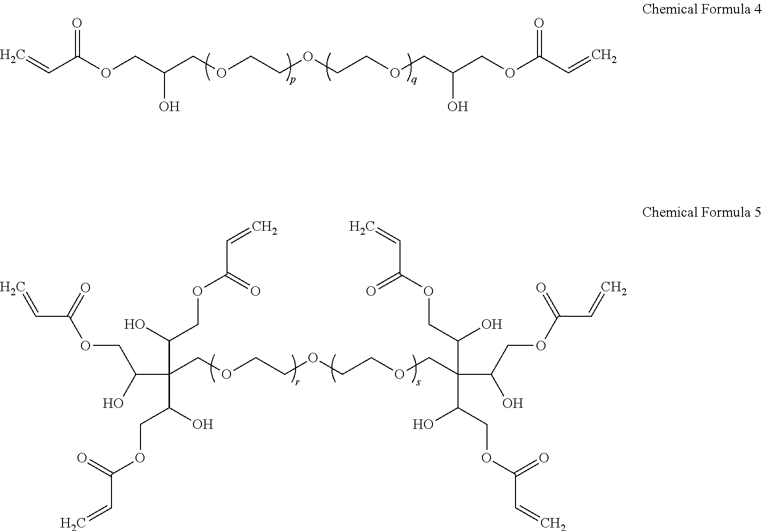

In Chemical Formula 4 and Chemical Formula 5,
p, q, r, and s may each independently be an integer from 1 to 10.

The photopolymerizable compound may be used after being treated with an acid anhydride to provide better developability.

The photopolymerizable compound may be included in an amount of about 1 part by weight to about 30 parts by weight, for example about 5 parts by weight to about 15 parts by weight based on 100 parts by weight of the resin. If the photopolymerizable compound is included within the described range, curing occurs sufficiently, reliability is excellent, heat resistance, light resistance, and chemical resistance of the pattern are improved, and resolution and adhesion are also improved.

### Photopolymerization Initiator

A photosensitive resin composition according to some example embodiments includes a photopolymerization initiator. The photopolymerization initiator may be an acetophenone-based compound, a benzophenone-based compound, a thioxanthone-based compound, a benzoin-based compound, a triazine-based compound, an oxime-based compound, and/or the like.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

Examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

Examples of the thioxanthone-based compound may be thioxanthone, 2-chlorothioxanthone, 2-methylthioxanthone, isopropyl thioxanthone, 2,4-diethyl thioxanthone, 2,4-diisopropyl thioxanthone, and/or the like.

Examples of the benzoin-based compound may be benzoin, benzoin methyl ether, benzoin ethyl ether, benzoin isopropyl ether, benzoin isobutyl ether, benzyl dimethyl ketal, and/or the like.

Examples of the triazine-based compound may be 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

Examples of the oxime-based compound may include O-acyloxime compounds, 2-(O-benzoyloxime)-1-[4-(phenylthio)phenyl]-1,2-octanedione, 1-(0-acetyloxime)-1-[9-ethyl-6-(2-methylbenzoyl)-9H-carbazol-3-yl]ethanone, 0-ethoxycarbonyl-α-oxyamino-1-phenylpropan-1-one, and/or the like. Some examples of the O-acyloxime-based compound may include 1,2-octanedione, 2-dimethylamino-2-(4-methylbenzyl)-1-(4-morpholin-4-yl-phenyl)-butan-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octane-1-one oxime-O-acetate, 1-(4-phenylsulfanylphenyl)-butane-1-one oxime-O-acetate, and/or the like.

In addition to the described compound, the photopolymerization initiator may also include a carbazole compound, a diketone compound, a sulfonium borate compound, a diazo compound, an imidazole compound, a biimidazole compound, a fluorene compound, and/or the like.

The photopolymerization initiator may be included in an amount of about 1 part by weight to about 10 parts by weight, for example about 1 part by weight to about 7 parts by weight, based on 100 parts by weight of the resin. If (e.g., when) the photopolymerization initiator is included within the described range, photopolymerization occurs sufficiently, resulting in excellent sensitivity and improved transmittance.

### Solvent

The solvent may be a material that is compatible with, but does not react with, the resin, the photopolymerizable compound, and the photopolymerization initiator.

Examples of the solvent may include alcohols such as methanol, ethanol, and/or the like; ethers such as dichloroethyl ether, n-butyl ether, diisoamyl ether, methylphenyl ether, tetrahydrofuran, and/or the like; glycol ethers such as ethylene glycol monomethyl ether, ethylene glycol monoethyl ether, ethylene glycoldimethylether, and/or the like; cellosolve acetates such as methyl cellosolve acetate, ethyl cellosolve acetate, diethyl cellosolve acetate, and/or the like; carbitols such as methyl ethylcarbitol, diethyl carbitol, diethylene glycol monomethyl ether, diethylene glycol monoethyl ether, diethylene glycoldimethylether, diethylene glycol ethylmethyl ether, diethylene glycol diethyl ether, and/or the like; propylene glycol alkylether acetates such as propylene glycol methylether acetate, propylene glycol propyl ether acetate, and/or the like; aromatic hydrocarbons such as toluene, xylene, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; oxy acetic acid alkyl esters such as oxy methyl acetate, oxy ethyl acetate, oxy butyl acetate, and/or the like; alkoxy acetic acid alkyl esters such as methoxy methyl acetate, methoxy ethyl acetate, methoxy butyl acetate, ethoxy methyl acetate, ethoxy ethyl acetate, and/or the like; 3-oxypropionic acid alkyl esters such as 3-oxymethyl propionate, 3-oxyethyl propionate, and/or the like; 3-alkoxypropionic acid alkyl esters such as 3-methoxymethyl propionate, 3-methoxyethyl propionate, 3-ethoxyethyl propionate, 3-ethoxymethyl propionate, and/or the like; 2-oxypropionic acid alkyl esters such as 2-oxymethyl propionate, 2-oxyethyl propionate, 2-oxypropyl propionate, and/or the like; 2-alkoxypropionic acid alkyl esters such as 2-methoxymethyl propionate, 2-methoxyethyl propionate, 2-ethoxyethyl propionate, 2-ethoxymethyl propionate, and/or the like; 2-oxy-2-methylpropionic acid esters such as 2-oxy-2-methylmethyl propionate, 2-oxy-2-methylethyl propionate, and/or the like, monooxy monocarboxylic acid alkyl esters of 2-alkoxy-2-methyl alkyl propionates such as 2-methoxy-2-methylmethyl propionate, 2-ethoxy-2-methylethyl propionate, and/or the like; esters such as 2-hydroxyethyl propionate, 2-hydroxy-2-methylethyl propionate, hydroxy ethyl acetate, 2-hydroxy-3-methyl methyl butanoate, and/or the like; ketonate esters such as ethyl pyruvate, and/or the like. Additionally, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, 3-methyl benzoate, ethylene carbonate, propylene carbonate, phenyl cellosolve acetate, and/or the like may be also used.

The solvent may be included in an amount of about 100 parts by weight to about 500 parts by weight based on 100 parts by weight of the resin. If the solvent is included within the range, the photosensitive resin composition has appropriate viscosity, resulting in excellent processability if (e.g., when) manufacturing photosensitive resin layers.

### Other Additives

The photosensitive resin composition according to some example embodiments may further include other additives.

The photosensitive resin composition may include additives such as a sensitizer such as a diacid (e.g., malonic acid), an alkanolamine (e.g., 3-amino-1,2-propanediol, N-phenyldiethanolamine, and/or the like), a leveling agent, a silane coupling agent, a surfactant, an epoxy compound, a thermal latent acid generator, a development control agent, a curing agent, or a combination thereof, in order to prevent stains or spots during coating, leveling properties, or the generation of residues due to non-development. An amount of these additives used can be easily adjusted depending on the desired physical properties.

For example, the silane coupling agent may have a reactive substituent such as a vinyl group, carboxyl group, methacryloxy group, isocyanate group, or epoxy group to improve adhesion to the substrate, and may have a different structure from the silane compound.

Examples of the silane coupling agent may include trimethoxysilyl benzoic acid, γ-methacryloxy propyl trimethoxysilane, vinyl triacetoxysilane, vinyl trimethoxysilane, γ-isocyanate propyl triethoxysilane, γ-glycidoxy propyl trimethoxysilane, β-(3,4-epoxycyclohexyl)ethyltrimethoxysilane, and/or the like. These may be used alone or in a mixture of two or more.

The silane coupling agent may be included in an amount of about 0.01 parts by weight to about 10 parts by weight based on 100 parts by weight of the photosensitive resin composition. If the silane coupling agent is included within the described range, adhesion, storage properties, and/or the like are improved.

For example, the surfactant may be added to prevent film thickness unevenness or improve developability, and may include a fluorine-based surfactant and/or a silicone-based surfactant.

Examples of the fluorine-based surfactant may be a commercial fluorine-based surfactant such as BM-1000®, BM-1100®, and/or the like of BM Chemie Inc.; MEGAFACE F 142D®, MEGAFACE F 172®, MEGAFACE F 173®, MEGAFACE F 183®, MEGAFACE F 554®, and/or the like of DIC Co., Ltd.; FULORAD FC-135®, FULORAD FC-170C®, FULORAD FC-430®, FULORAD FC-431®, and/or the like of SUMITOMO 3M Co., Ltd.; SURFLON S-112®, SURFLON S-113®, SURFLON S-131®, SURFLON S-141®, SURFLON S-145®, and/or the like of Asahi Glass Co., Ltd.; SH-28PA®, SH-190®, SH-193®, SZ-6032®, SF-8428®, and/or the like of, Toray Silicone Co., Ltd.

The silicone-based surfactant may be a commercial silicone-based surfactant such as BYK-307, BYK-333, BYK-361 N, BYK-051, BYK-052, BYK-053, BYK-067A, BYK-077, BYK-301, BYK-322, BYK-325, BYK-378, and/or the like of BYK Chem.

The surfactant may be used in an amount of about 0.001 parts by weight to about 5 parts by weight based on 100 parts by weight of the photosensitive resin composition. if the surfactant is included within the described range, coating uniformity can be ensured, stains cannot occur, and wetting on ITO substrates or glass substrates, Si wafers or SiNₓ wafers, and Cu substrates can be improved.

In some embodiments, the photosensitive resin composition further includes an epoxy compound to improve adhesion and the like with a substrate. Examples of the epoxy compound may include a phenol novolac epoxy compound, a tetramethyl biphenyl epoxy compound, a bisphenol A epoxy compound, an alicyclic epoxy compound, or a combination thereof.

The epoxy compound may be used in an amount of about 0.01 part by weight to about 5 parts by weight based on 100 parts by weight of the resin composition. If (e.g., when) the epoxy compound is included within the described range, storage properties, adhesive force, and other properties can be improved.

Additionally, the photosensitive resin composition may further include a thermal latent acid generator. Examples of the thermal latent acid generator may include aryl sulfonic acids such as p-toluenesulfonic acid and benzenesulfonic acid; perfluoroalkyl sulfonic acids such as trifluoromethanesulfonic acid, trifluorobutane sulfonic acid, and/or the like; alkyl sulfonic acids such as methanesulfonic acid, ethane sulfonic acid, butane sulfonic acid, and/or the like; or a combination thereof, but is not limited thereto.

Furthermore, the photosensitive resin composition may include other additives such as an antioxidant, a stabilizer, and/or the like in a predetermined amount unless they deteriorate properties of the photosensitive resin composition.

Some example embodiments provide a photosensitive resin layer, such as a semiconductor redistribution layer insulating layer, manufactured by exposing, developing, and curing the aforementioned photosensitive resin composition.

The photosensitive resin layer (semiconductor redistribution layer insulating layer) manufacturing method is as follows.

### Coating and Film Formation

The photosensitive resin composition may be coated to have a desired thickness on a substrate such as a glass substrate or ITO substrate, Si wafer or SiNx wafer, Cu substrate, and/or the like which undergoes a predetermined pretreatment, using a spin or slit coating method, a roll coating method, a screen-printing method, an applicator method, and the like, and is heated at about 70° C. to about 150° C. for about 1 minute to 10 minutes to remove a solvent and thereby to form a film.

### Exposure

After disposing a mask to form a necessary pattern on the obtained photosensitive resin layer, exposure may be performed by irradiating an actinic ray of 200 nanometer (nm) to 500 nm. As a light source used for irradiation, a low-pressure mercury lamp, a high-pressure mercury lamp, an ultra-high pressure mercury lamp, a metal halide lamp, an argon gas laser, and/or the like, may be used, and in some cases, an X-ray, an electron beam, and/or the like may be used.

The exposure dose varies depending on the type (or kind), mixing amount, and dry film thickness of each component of the composition, but is less than 500 millijoule per square centimeter (mJ/cm²) (based on a 365 nm sensor) when using a high-pressure mercury lamp.

### Development

In the development method, following the exposure step, alkali aqueous solution or an organic solvent may be used as a developer to dissolve and remove unnecessary parts, leaving only the exposed parts remaining to form a pattern.

### Post-Processing

There may be a post-heating process to obtain a pattern excellent in terms of heat resistance, light resistance, adhesion, crack resistance, chemical resistance, high strength, and storage stability of the image pattern obtained by development in the described process. For example, after development, it may be heated in a nitrogen atmosphere in an oven at 200° C. to 400° C. for more than 1 hour.

Some example embodiments provide a semiconductor device including the photosensitive resin layer (semiconductor redistribution layer insulating layer).

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinafter, examples of the present disclosure will be described. However, the following examples are merely one or more potential example embodiments, and the present disclosure is not limited by the following examples.

### EXAMPLES

### Synthesis of Precursor Resin

A four-necked flask equipped with a stirrer, a temperature controller, a nitrogen gas injection device, and a condenser was filled with 600 gram (g) of γ-butyrolactone (GBL), a monoanhydride monomer, and/or a dianhydride monomer while passing nitrogen therethrough, 2-hydroxyethyl methacrylate (HEMA) was added, and pyridine was added while stirring at room temperature to obtain a reaction mixture. After 16 hours of reaction at room temperature, the solution was cooled to −10° C. and dicyclohexyl carbodiimide (DCC) and 250 g of GBL was added dropwise over 30 minutes. After stirring for an additional 5 minutes, a solution of 300 g of diamine monomer and GBL was added over 40 minutes and stirred for an additional 2 hours. After performing a reaction at room temperature for 1 hour, 30 g of ethanol was added thereto and then, stirred for 1 hour. Subsequently, GBL was added thereto, until the reaction solution had a solid content of 18%, and then, added to 3 liters of ethanol, obtaining precipitates. The polymer was filtered therefrom and dissolved in 1.5 liters of tetrahydrofuran (THF) and then, added in a dropwise fashion to 30 liters of water to produce precipitates, which were vacuum-dried. A precursor resin was prepared by drying at 50° C. under reduced pressure for more than 24 hours. At this time, the resin molecular weight was confirmed through a polystyrene calibration curve. The types (or kinds) and mixed mole numbers of the diamine monomers and dihydride monomers used are as shown in Table 1.

TABLE 1

| | | Synthesis | Synthesis | Synthesis | Synthesis | Synthesis |
|---|---|---|---|---|---|---|
| | | Example | Example | Example | Example | Example |
| | | 1 | 2 | 3 | 4 | 5 |
| Dianhydride | Chemical | 30 | 20 | 50 | — | — |
| monomer | Formula A | | | | | |
| | Chemical | 20 | 30 | — | 50 | — |
| | Formula B | | | | | |
| | Chemical | 50 | 50 | 50 | 50 | 100 |
| | Formula C | | | | | |
| Diamine | Chemical | 100 | 100 | 100 | 100 | 100 |
| monomer | Formula D | | | | | |

| | | | | | |
|---|---|---|---|---|---|
| Weight average | 22,000 | 21,000 | 25,000 | 20,000 | 15,000 |
| molecular weight (g/mol) | | | | | |

Chemical Formula A 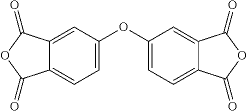 [SMILES: O=C1OC(=O)c2cc(Oc3ccc4c(c3)C(=O)OC4=O)ccc21]
Chemical Formula B 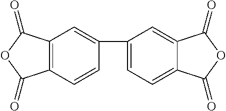 [SMILES: O=C1OC(=O)c2cc(-c3ccc4c(c3)C(=O)OC4=O)ccc21]
Chemical Formula C 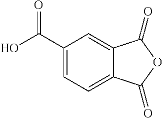 [SMILES: O=C(O)c1ccc2c(c1)C(=O)OC2=O]
Chemical Formula D

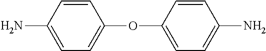 [SMILES: Nc1ccc(Oc2ccc(N)cc2)cc1]

### Preparation of Photosensitive Resin Composition

### Example 1

33 g of the polyamic ester-based resin of Synthesis Example 1, 48 g of GBL (gamma butyrolactone) and 12 g of DMSO (dimethylsulfoxide) as a solvent, 4 g of tetra ethylene glycol dimethacrylate and 0.6 g of diurethane dimethacrylate as a photopolymerizable compound, 1 g of a silane coupling agent (KBM-573), and 0.1 g of N-phenyldiethanolamine were added, and 0.1 g of F-554 (DIC Co., Ltd.) as a fluorine-type (or kind) leveling agent was added thereto and then, sufficiently stirred. Subsequently, the obtained mixture was filtered with a 0.45 micrometer (μm) polypropylene resin filter to obtain a negative-type (or kind) photosensitive resin composition.

### Example 2

A photosensitive resin composition was prepared in the same manner as in Example 1 except that the polyamic ester-based resin of Synthesis Example 2 was used instead of the polyamic ester-based resin of Synthesis Example 1.

### Example 3

A photosensitive resin composition was prepared in the same manner as in Example 1 except that the polyamic ester-based resin of Synthesis Example 3 was used instead of the polyamic ester-based resin of Synthesis Example 1.

### Example 4

A photosensitive resin composition was prepared in the same manner as in Example 1 except that the polyamic ester-based resin of Synthesis Example 4 was used instead of the polyamic ester-based resin of Synthesis Example 1.

### Example 5

A photosensitive resin composition was prepared in the same manner as in Example 1 except that the polyamic ester-based resin of Synthesis Example 5 was used instead of the polyamic ester-based resin of Synthesis Example 1.

### Comparative Example 1

A photosensitive resin composition was prepared in the same manner as in Example 1 except that 4.6 g of tetra ethylene glycol dimethacrylate was used as the photopolymerizable compound.

### Comparative Example 2

A photosensitive resin composition was prepared in the same manner as in Example 2 except that 4.6 g of tetra ethylene glycol dimethacrylate was used as the photopolymerizable compound.

### Comparative Example 3

A photosensitive resin composition was prepared in the same manner as in Example 3 except that 4.6 g of tetra ethylene glycol dimethacrylate was used as the photopolymerizable compound.

### Comparative Example 4

A photosensitive resin composition was prepared in the same manner as in Example 4 except that 4.6 g of tetra ethylene glycol dimethacrylate was used as the photopolymerizable compound.

### Comparative Example 5

A photosensitive resin composition was prepared in the same manner as in Example 5 except that 4.6 g of tetra ethylene glycol dimethacrylate was used as the photopolymerizable compound.

### Comparative Example 6

A photosensitive resin composition was prepared in the same manner as in Example 1 except that the diurethane dimethacrylate was not used.

### Evaluation 1: Sensitivity Evaluation

Each of the photosensitive resin compositions of Examples 1 to 5 and Comparative Examples 1 to 6 was coated on an 8 inch Cu wafer and then, heated at 100° C. on a hot plate for 4 minutes to form a 7 μm-thick photosensitive resin layer. The photosensitive resin layer was exposed to light by using i10c made by Nikon Precision Inc., treated with cyclopentanone for 20 seconds, double-puddled for 20 seconds, rinsed with PGMEA for 1 minute, and cured at 220° C. in an oven for 2 hours under a nitrogen atmosphere to form a cured layer (cured wafer) with 20 μm hole pattern. The cured layer was examined through CD-SEM made by Hitachi, Ltd. to check Exp. Dose (Eop) where the 20 μm hole pattern was realized.

### Evaluation 2: CTE Evaluation

The cured wafers of Evaluation 1 were immersed in a 1% fluoric acid solution to obtain PI films, and the films detached therefrom were used to measure TMA by scanning to 400° C. at 10° C./min, and the results are shown in Table 2.

### Evaluation 3: Adhesive Strength Evaluation

After EMC molding on the cured wafers of Evaluation 1, a die shear tester (DAGE series 4000PXY, DAGE) was used to measure adhesive strength, and the results are shown in Table 2.

### Evaluation 4: Reliability Evaluation

The cured wafers of Evaluation 1 were driven for 2000 cycles of a thermal cycle (−55° C. to 125° C.) which is a reliability condition. Subsequently, field emission scanning electron microscopy (FE-SEM) was used to check whether or not cracks occur between PI and Cu, and the results are shown in Table 2.

TABLE 2

| | | | Adhesive | |
|---|---|---|---|---|
| | Eop | CTE | strength | |
| | (msec) | (ppm) | (kgf) | Reliability |
| Example 1 | 470 | 33 | 20 | OK |
| Example 2 | 480 | 32 | 21 | OK |
| Example 3 | 460 | 32 | 20 | OK |
| Example 4 | 450 | 25 | 20 | OK |
| Example 5 | 450 | 25 | 21 | OK |
| Comparative Example 1 | 510 | 45 | 16 | OK |
| Comparative Example 2 | 520 | 46 | 15 | OK |
| Comparative Example 3 | 510 | 45 | 16 | OK |
| Comparative Example 4 | 500 | 38 | 16 | OK |
| Comparative Example 5 | 490 | 39 | 16 | OK |
| Comparative Example 6 | 550 | 60 | 14 | NG |

Referring to Table 1, the photosensitive resin composition according to one or more example embodiments exhibits excellent sensitivity and CTE characteristics, very excellent adhesive strength to a copper layer, and excellent reliability and thus may be suitable for use as a composition for a semiconductor redistribution layer.

A person of ordinary skill in the art, in view of the present disclosure in its entirety, would appreciate that each suitable feature of the embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

While this disclosure has been described in connection with what is presently considered to be practical example embodiments, it is to be understood that the present disclosure is not limited to the disclosed embodiments, but, on the contrary, is intended to cover various modifications and equivalent arrangements included within the spirit and scope of the appended claims, and equivalents thereof. Therefore, the aforementioned embodiments should be understood to be exemplary but not limiting the present disclosure in any way.

What is claimed is:

1. A resin composition, comprising:
a resin;
a photopolymerizable compound comprising a compound represented by Chemical Formula 1;
a photopolymerization initiator; and
a solvent, 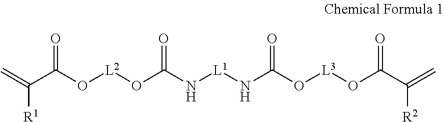
wherein in Chemical Formula 1,
R¹ and R² are each independently a hydrogen atom or a substituted or unsubstituted C1 to C20 alkyl group, and
L¹ to L³ are each independently a substituted or unsubstituted C1 to C20 alkylene group, a substituted or unsubstituted C3 to C20 cycloalkylene group, a substituted or unsubstituted C6 to C20 arylene group, or a combination thereof, and
wherein the resin composition is a photosensitive resin composition.

2. The resin composition as claimed in claim 1, wherein:
R¹ and R² are each independently a methyl group.

3. The resin composition as claimed in claim 1, wherein:
L² and L³ are each independently an unsubstituted C1 to C20 alkylene group.

4. The resin composition as claimed in claim 1, wherein:
L¹ is represented by Chemical Formula L: 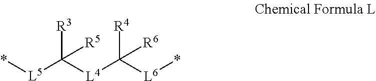
wherein in Chemical Formula L,
R³ to R⁶ are each independently a hydrogen atom or a substituted or unsubstituted C1 to C20 alkyl group, wherein at least one selected from among R³ and R⁵ is a substituted or unsubstituted C1 to C20 alkyl group, and at least one selected from among R⁴ and R⁶ is a substituted or unsubstituted C1 to C20 alkyl group, and
L⁴ to L⁶ are each independently an unsubstituted C1 to C20 alkylene group.

5. The resin composition as claimed in claim 4, wherein:
L⁵ and L⁶ are different from each other.

6. The resin composition as claimed in claim 1, wherein:
the compound represented by Chemical Formula 1 has an asymmetric structure.

7. The resin composition as claimed in claim 1, wherein
the photopolymerizable compound further comprises a compound having a different structure from the compound represented by Chemical Formula 1.

8. The resin composition as claimed in claim 1, wherein:
the resin is a polyamic acid or polyamic ester resin comprising a structural unit represented by Chemical Formula 2: 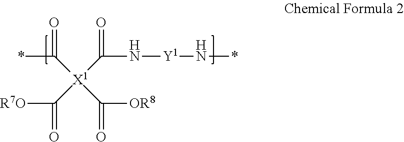
wherein in Chemical Formula 2,
X¹ is a moiety derived from a monoanhydride monomer or a dianhydride monomer,
Y¹ is a moiety derived from a diamine monomer, and
R⁷ and R⁸ are each independently a substituted or unsubstituted C1 to C20 alkyl group, a substituted or unsubstituted C3 to C20 cycloalkyl group, a substituted or unsubstituted C6 to C20 aryl group or a substituted or unsubstituted C2 to C20 heterocyclic group.

9. The resin composition as claimed in claim 8, wherein:
the monoanhydride monomer or dianhydride monomer is represented by Chemical Formula 2-1 or Chemical Formula 2-2: 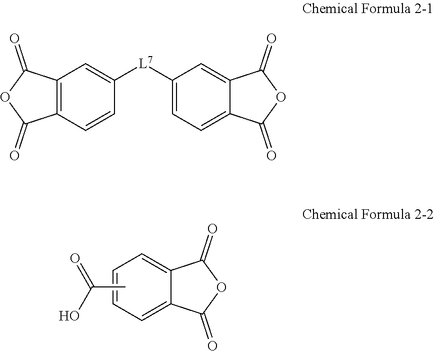
wherein in Chemical Formula 2-1,
L⁷ is a single bond, *—O—*, *—S—*, *—C≡C—*, *—C(═O)—*, *—C(═O)O—*, *—NR⁰—* (R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

10. The resin composition as claimed in claim 9, wherein:
the resin comprises a moiety derived from the monoanhydride monomer represented by Chemical Formula 2-2.

11. The resin composition as claimed in claim 8, wherein:
the diamine monomer is represented by Chemical Formula 2-3 or Chemical Formula 2-4: 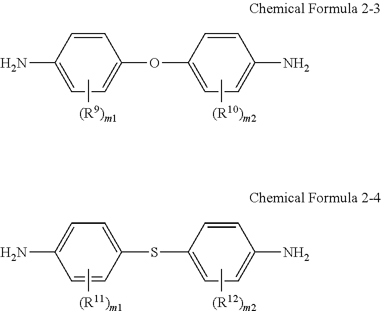
wherein in Chemical Formula 2-3 and Chemical Formula 2-4,
R¹¹ and R¹² are each independently a halogen atom, a hydroxy group, a substituted or unsubstituted C1 to C20 alkyl group, or a substituted or unsubstituted C1 to C20 alkoxy group, and
m1 and m2 are each independently an integer from 0 to 4.

12. The resin composition as claimed in claim 1, wherein:
the photosensitive resin composition comprises,
based on 100 parts by weight of the resin,
the photopolymerizable compound in an amount of about 1 part by weight to about 30 parts by weight,
the photopolymerization initiator in an amount of about 1 part by weight to about 10 parts by weight, and
the solvent in an amount of about 100 parts by weight to about 500 parts by weight.

13. The resin composition as claimed in claim 1, wherein:
the resin composition is a photosensitive resin composition comprising a negative-type photosensitive resin composition.

14. A resin layer manufactured using the photosensitive resin composition as claimed in claim 1,
wherein the resin layer is a photosensitive resin layer.

15. The resin layer as claimed in claim 14, wherein:
the resin layer is a photosensitive resin layer comprising a semiconductor redistribution layer insulating layer.

16. A semiconductor device comprising the photosensitive resin layer as claimed in claim 14.

17. A method comprising:
preparing and mixing a mixture; and
filtering the mixture,
wherein the mixture comprises:
a resin;
a photopolymerizable compound represented by Chemical Formula 1;
a photopolymerization initiator; and
a solvent, 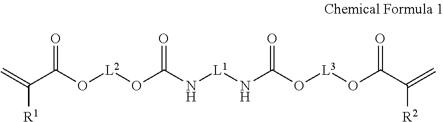
wherein in Chemical Formula 1,
R¹ and R² are each independently a hydrogen atom or a substituted or unsubstituted C1 to C20 alkyl group, and
L¹ to L³ are each independently a substituted or unsubstituted C1 to C20 alkylene group, a substituted or unsubstituted C3 to C20 cycloalkylene group, a substituted or unsubstituted C6 to C20 arylene group, or a combination thereof,
wherein the method is a method of manufacturing a photosensitive resin composition.

18. The method of claim 17, wherein the photosensitive resin composition comprises, based on 100 parts by weight of the resin:
the photopolymerizable compound in an amount of about 1 part by weight to about 30 parts by weight;
the photopolymerization initiator in an amount of about 1 part by weight to about 10 parts by weight; and
the solvent in an amount of about 100 parts by weight to about 500 parts by weight.

19. A method comprising:
applying a photosensitive resin composition to a wafer; and
heating the resin composition to form a photosensitive resin layer,
wherein the photosensitive resin composition comprises:
a resin;
a photopolymerizable compound represented by Chemical Formula 1;
a photopolymerization initiator; and
a solvent, 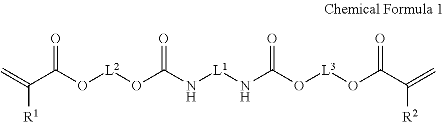
wherein in Chemical Formula 1,
R¹ and R² are each independently a hydrogen atom or a substituted or unsubstituted C1 to C20 alkyl group, and
L¹ to L³ are each independently a substituted or unsubstituted C1 to C20 alkylene group, a substituted or unsubstituted C3 to C20 cycloalkylene group, a substituted or unsubstituted C6 to C20 arylene group, or a combination thereof,
wherein the method is a method of manufacturing the photosensitive resin layer.

20. The method of claim 19, wherein a thickness of the photosensitive resin layer is about 7 micrometer (μm).
